(19) United States
(12) Patent Application Publication
(10) Pub. No.: US 2011/0021020 A1
(43) Pub. Date: Jan. 27, 2011

(54) SEMICONDUCTOR DEVICE AND FABRICATION PROCESS THEREOF

(75) Inventors: Hisaya Sakai, Kawasaki (JP); Noriyoshi Shimizu, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU SEMICONDUCTOR LIMITED, Yokohama-shi (JP)

(21) Appl. No.: 12/895,002

(22) Filed: Sep. 30, 2010

Related U.S. Application Data
(62) Division of application No. 11/785,949, filed on Apr. 23, 2007.

(30) Foreign Application Priority Data
Sep. 20, 2006 (JP) 2006-254426

(51) Int. Cl. H01L 21/4763

(52) U.S. Cl. 438/637; 257/E21.495

(57) ABSTRACT

A semiconductor device includes a first interconnection pattern embedded in a first insulation film, a second insulation film covering the first interconnection pattern over the first insulation film, an interconnection trench formed in an upper part of the second insulation film, a via-hole extending downward from the interconnection trench at a lower part of the second insulation film, the via-hole exposing the first interconnection pattern, a second interconnection pattern filling the interconnection trench, a via-plug extending downward in the via-hole from the second interconnection pattern and making a contact with the first interconnection pattern, and a barrier metal film formed between the second interconnection pattern and the interconnection trench, the barrier metal film covering a surface of the via-plug continuously, wherein the via-plug has a tip end part invading into the first interconnection pattern across a surface of said first interconnection pattern, the interconnection trench has a flat bottom surface, and the barrier metal film has a larger film thickness at the tip end part of the via-plug as compared with a sidewall surface of the via-plug.

### CROSS-REFERENCE TO RELATED APPLICATION

This application is a divisional of U.S. application Ser. No. 11/785,949, filed on Apr. 23, 2007 which is based on Japanese priority application No. 2006-254426 filed on Sep. 20, 2006, the entire contents of which are hereby incorporated by reference.

### BACKGROUND OF THE INVENTION

The present invention generally relates to semiconductor devices and more particularly to a semiconductor device having a multilayer interconnection structure and fabrication process thereof.

Semiconductor integrated circuit devices of these days use so-called multilayer interconnection structure of damascene or dual damascene structure, in which a low-resistance Cu interconnection pattern is embedded in a low-K interlayer insulation film, for connecting large number of semiconductor elements formed on a substrate.

With the multilayer interconnection structure of damascene or dual damascene structure, an interconnection trench or contact hole is formed in an interlayer insulation film of low-K dielectric film, and it is practiced to fill such an interconnection trench or contact hole with a Cu layer. Further, unnecessary Cu layer on the interlayer insulation film is removed by a CMP (chemical mechanical polishing) process.

With such a multilayer interconnection structure having a Cu interconnection pattern, it is important to form a barrier metal film of refractory metal typically of Ta or Ti, or a conductive compound thereof, on the surface of the interconnection trench or contact hole for preventing diffusion of Cu into the interlayer insulation film.

Because such a barrier metal film has to be deposited at a low temperature for avoiding damaging of the low-K dielectric interlayer insulation film, film formation of the barrier metal film is carried out conventionally by a sputtering process.

Patent Reference 1: U.S. Patent Application Publication 2006/0189115

Patent Reference 2: U.S. Patent Application Publication 2005/0151263

### SUMMARY OF THE INVENTION

FIGS. 1A-1C are diagrams showing the process of forming a multilayer interconnection structure according to a related art of the present invention.

Referring to FIG. 1A, there is formed an interlayer insulation film 11 on a substrate not illustrated and an interconnection pattern 11A is embedded therein, wherein the sidewall surface and bottom surface of the interconnection pattern 11A is covered with a barrier metal film 11a such as a Ta film.

On the interlayer insulation film 11, there is formed a hard mask layer 12 of SiC, SiN, or the like, and low-K dielectric films 13 and 15 are formed further on the hard mask layer 12 in the state in which another hard mask layer 14 is interposed between the low-K dielectric interlayer insulation films 13 and 15.

With the state of FIG. 1A, there is formed an interconnection trench 15A in the interlayer insulation film 15 so as to expose the surface of the interlayer insulation film 13 underneath, and there is further formed a via-hole 13A in the interconnection trench 15A so as to expose the surface of the interconnection pattern 11A.

Next, in the step of FIG. 1B, a barrier metal film 16 such as a Ta film is deposited on the structure of FIG. 1A by a sputtering process, wherein the interconnection trench 15A and the via-hole 13A of FIG. 1B are filled with a Cu layer in the step of FIG. 1C. Further, by removing the unnecessary Cu layer on the interlayer insulation film 15 by a CMP process, there is formed a Cu interconnection pattern 15B filling the interconnection trench 15A and having a Cu via-plug 13B filling the via-hole 13A, wherein the Cu via-plug 13B is formed in contact with the interconnection pattern 11A.

Meanwhile, there is a proposal, with such a multilayer interconnection structure, to conduct a bias sputter-etching process after the process of FIG. 2A corresponding to FIG. 1B as shown in FIG. 2B and dig the surface of the interconnection pattern 11A in correspondence to the via-hole 13A for ensuring contact between the via-plug 13B and the interconnection pattern 11A and for reducing the contact resistance.

By digging the surface of the interconnection pattern 11A by the sputter-etching process as such, a reliable contact is attained between the Cu via-plug 13B and the interconnection pattern 11A as shown in FIG. 2C when the via-hole 13A and the interconnection trench 15A are filled with the Cu plug 13B and the Cu interconnection pattern 15B, respectively. Further, as a result of such a sputter-etching process, the barrier metal film deposited on the bottom part of the via-plug 13A is also subjected to sputter-etching, and the barrier metal film thus sputter-etched cause deposition again on the sidewall surface of the via-hole 13A. With this, it becomes possible to form a thick barrier metal film on the sidewall surface of the via-hole 13A, which tends to suffer from the problem of poor step coverage.

On the other hand, in the case the process of FIG. 2B is conducted after the step of FIG. 2A, the bottom surface of the interconnection trench 15A also experiences the sputter-etching process, and there arises a problem that irregular projections and depressions may be formed in such a sputter-etched part. When such projections and depressions are formed at the bottom of the interconnection trench 15A, coverage of the interconnection trench 15A by the barrier metal film 16 tends to become non-uniform particularly the bottom surface thereof and there is a concern that the barrier metal film 16 is lost in some part.

In the case such a device isolation trench 15A is filled with the Cu interconnection pattern in the state in which formation of the barrier metal film 16 is incomplete, there is caused diffusion of Cu from the Cu interconnection pattern 15B into the interlayer insulation film 13 and problems such as short circuit or peeling of the film are caused.

The present invention provides a semiconductor device, comprising:

a first interconnection pattern embedded in a first insulation film;

a second insulation film covering said first interconnection pattern over said first insulation film;

an interconnection trench formed in an upper part of said second insulation film;

a via-hole extending downward from said interconnection trench at a lower part of said second insulation film, said via-hole exposing said first interconnection pattern;

a second interconnection pattern filling said interconnection trench;

a via-plug extending downward in said via-hole from said second interconnection pattern and making a contact with said first interconnection pattern; and

a barrier metal film formed between said second interconnection pattern and said interconnection trench, said barrier metal film covering a surface of said via-plug continuously,

wherein said via-plug has a tip end part invading into said first interconnection pattern across a surface of said first interconnection pattern,

said interconnection trench has a flat bottom surface, and

said barrier metal film has a larger film thickness at said sidewall surface of said via-plug as compared with a tip end part of said via-plug.

Further, the present invention provides a method for fabricating a semiconductor device, comprising the steps of:

forming an opening in an insulation film covering a conductor pattern so as to expose said conductor pattern;

depositing a conductor film on said insulation film so as to cover continuously a principal surface of said insulation film and a sidewall surface and a bottom surface of said opening; and

depositing a conductor material on said insulation film via said conductor film such that said conductor material fills said opening via said conductor film,

wherein said step of depositing said conductor film comprises:

a first sputtering step that deposits said conductor film under a first condition in which a deposition rate on said principal surface of said insulation film that becomes larger than a sputter-etching rate on said principal surface; and

a second sputtering step that deposits said conductor film under a second condition in which a deposition rate on said principal surface of said insulation film that becomes generally equal to a sputter-etching rate on said principal surface.

According to the present invention, it becomes possible to achieve a reliable contact between the via-plug and the lower layer interconnection pattern by causing the tip end part of the via-plug to invade downward beyond surface of the interconnection pattern at the time of forming the via-contact in the multilayer interconnection structure by damascene process or dual damascene process. Thereby, it should be noted that, because the barrier metal film covering the tip end part of the via-plug is sputter-etched with a larger rate in the second sputtering process than the barrier metal film at the bottom surface of the interconnection trench, it becomes possible to decrease the film thickness of the barrier metal film at the tip end part of the via-plug selectively, without sputter-etching the bottom surface of the interconnection trench substantially. Thereby, it becomes possible to realize a low-resistance contact to the lower layer interconnection pattern, without deteriorating the function of barrier metal film at bottom surface of the interconnection trench. Further, it should be noted that the barrier metal material thus sputter-etched from the barrier metal film covering the bottom part of the via-hole adheres to the sidewall surface of the via-hole, and it becomes possible to realize excellent step coverage for the barrier metal film formed by a sputtering process, even in the case the via-hole has a large aspect ratio.

Other objects and further features of the present invention will become apparent from the following detailed description when read in conjunction with the attached drawings.

### BRIEF DESCRIPTION OF THE DRAWINGS

FIGS. 1A-1C are diagrams showing the formation method of a multilayer interconnection structure according to a related art of the present invention;

FIGS. 2A-2C are diagrams showing the formation method of a multilayer interconnection structure according to another related art of the present invention;

FIG. 3 is a diagram showing construction of a magnetron sputtering apparatus used with the present invention;

FIG. 4 is a diagram explaining the principle of the present invention;

FIGS. 5A-5F are diagrams corresponding to FIG. 4 showing the principle of the present invention;

FIGS. 6A and 6B are further diagrams explaining the principle of the present invention;

FIG. 7 is a further diagram explaining the principle of the present invention;

FIGS. 8A-8E are diagrams showing the fabrication process of a semiconductor device according to a first embodiment of the present invention;

FIG. 9 is a diagram showing the step of FIG. 8B is shown in detail;

FIG. 10 is a diagram explaining the first embodiment of the present invention:

FIGS. 11A-11D are further diagrams explaining the first embodiment of the present invention; and

FIGS. 12A-12C are diagrams explaining a second embodiment of the present invention.

### DETAILED DESCRIPTION OF THE INVENTION

### Principle

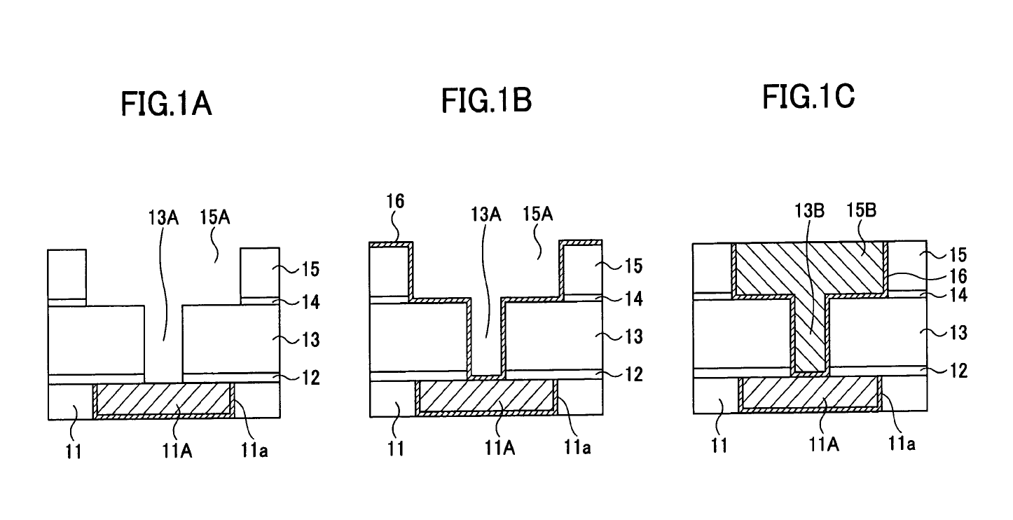

FIG. 1 shows the construction of a magnetron sputtering apparatus 100 used with the present invention.

Referring to FIG. 1, the magnetron sputtering apparatus 100 includes a processing vessel 101 that defines a processing space 101A inside a screening plate 101B such that the processing space 101A is evacuated from an evacuation port 101a, and a substrate W to be processed is held on a stage 102 at a lower part of the processing vessel 101.

The processing space 101A is supplied with an Ar gas and a nitrogen gas via respective lines 103A and 103B, and a target 104 such as a Ta target is held in the processing vessel so as to face the substrate W on the stage 102.

The target 104 is connected to a D.C. bias power supply 105, and plasma is induced in the processing space 101A under a reduced pressure environment by driving the D.C. bias power supply 105. The plasma thus formed cause sputtering of the target 104 and desired film formation is attained on the surface of the substrate W as the sputtered active species such as Ta⁰ or Ta⁺ reach the substrate W together with rare gas atoms in the plasma such as Ar⁺.

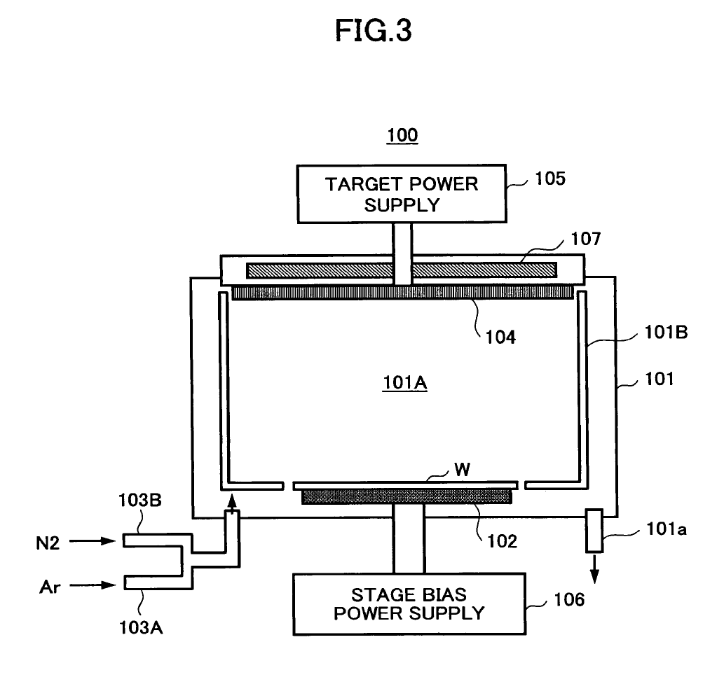

Further, with the magnetron sputtering apparatus 100 of FIG. 3, a stage bias power supply 106 is connected to the stage 102, and thus, it becomes possible to control the sputtering action caused at the surface of the substrate W by the collision of Ar⁺, or the like. Further, there is provided a rotary magnet 107 behind the target 104 and efficient and uniform sputtering is attained at the target 104 by applying a magnetic flux of the rotary magnet 107.

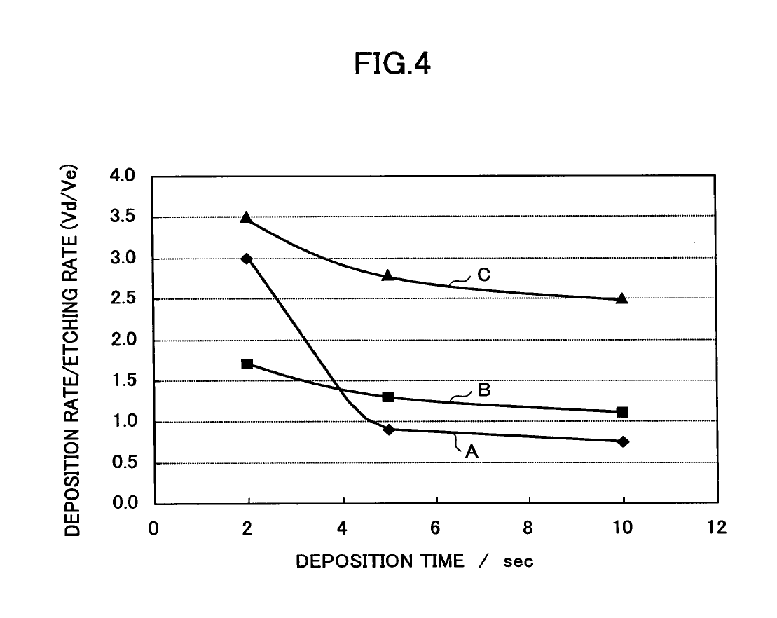

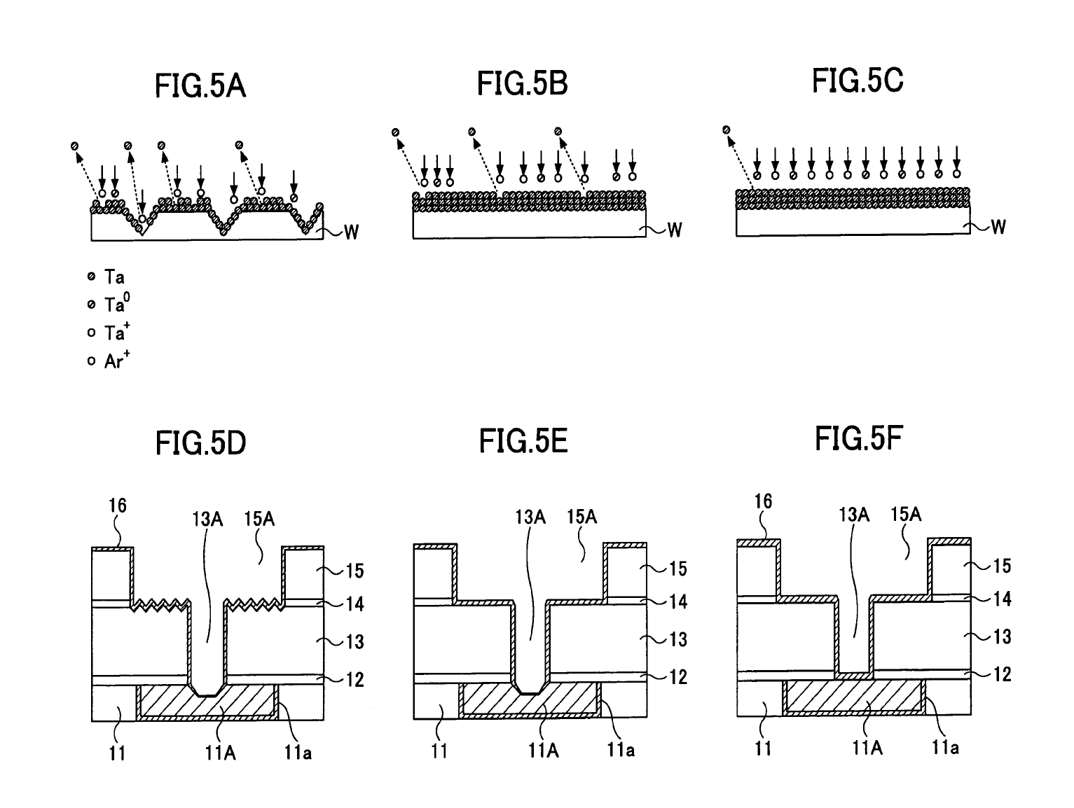

FIG. 4 is a diagram showing a ratio (Vd/Ve) between a deposition rate (Vd) and a sputter-etching rate (Ve) of a Ta film for the case of sputtering the Ta film on a flat surface under various process conditions A-C summarized in Table 1. Further, FIGS. 5A-5F are diagrams showing the state of the substrate surface corresponding to the process conditions A-C schematically. In the drawings, those parts corresponding to the parts explained previously are designated by the same reference numerals and explanation thereof will be omitted.

TABLE 1

| | (A) | (B) | (C) |
|---|---|---|---|
| Target power | 16 | 160 | 320 |
| density | | | |
| (mW/m²) | | | |
| Bias power | 10 | 6 | 6 |
| density | | | |
| (mW/m²) | | | |
| Pressure | 3E−1-7E−1 | 6E−2 | 4E−2 |
| (Pa) | | | |

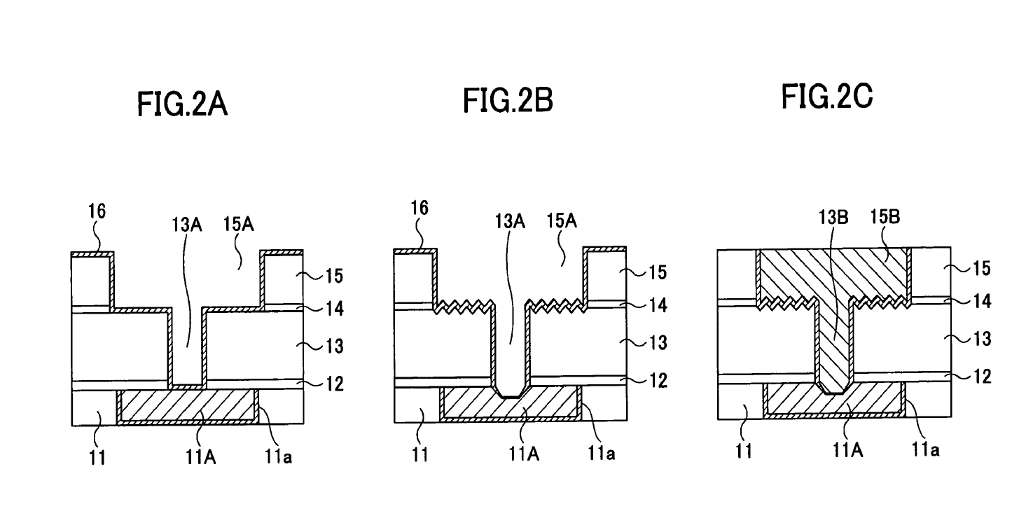

Referring to FIG. 4, it can be seen that deposition of Ta film is dominant (Vd/Ve>>1) in the case of using general bias sputtering condition (condition C) where the target electric power density is large and the bias electric power density is small. This corresponds to the situation shown in FIG. 5C. Thus, there is caused deposition of the Ta film on the sidewall surface and bottom surface of the interconnection trench 15A and on the sidewall surface and bottom surface of the via-hole 13A as shown in FIG. 5F. In this case, no sputtering action is attained at the surface of the substrate to be processed, and there occurs no digging at the surface of the conductor pattern 11A such as the one explained in FIG. 2B.

On the other hand, in the case of bias sputtering (condition A), in which the target electric power density is small, sputter-etching of the Ta film becomes dominant (Vd<Ve) as shown in FIG. 4. This corresponds to the situation shown in FIG. 5A. Thus, there is formed a desired depression in the conductor pattern 11A as shown in FIG. 5D as a result of digging caused at the bottom of the via-hole 13A. On the other hand, in the case of conducting the sputter-etching process under the condition A, there is caused sputter-etching also at the bottom part of the interconnection trench 15A, and thus, there can be a case shown in which the barrier metal film 16 covering the bottom part of the interconnection trench 15A is lost partially as shown in FIG. 5D.

The condition B is intermediate of the condition A and the condition C and causes the deposition and sputtering of the Ta film with generally the same degree (Vd≈Ve) as shown in FIG. 4. This corresponds to the situation shown in FIG. 5B. In this case, it becomes possible to form a depression on the surface of the conductor pattern 11A by digging the surface thereof as a result of promoted sputter-etching process at the bottom of the via-hole 13A while effectively suppressing the sputter-etching at the bottom part of the interconnection trench 15A as shown in FIG. 5E.

Meanwhile, the inventor of the present invention has discovered, in the experiments of FIGS. 5A-5F, in that the sputter-etching amount at the bottom part of the via-hole 13A and the sputter-etching amount at the bottom part of the interconnection trench 15A can be changed relatively to each other by changing the sputter-etching condition.

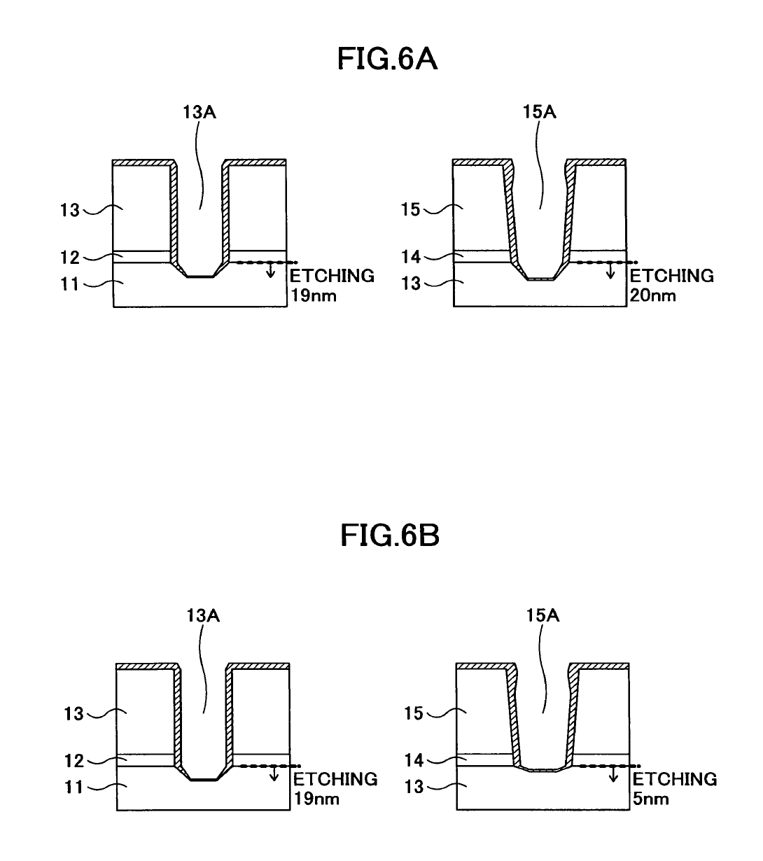

FIGS. 6A and 6B are diagrams each showing the situation of sputter-etching at the bottom part of the via-hole 13A and at the bottom part of the interconnection trench 15A, respectively for the case the bias sputtering of the Ta film is conducted under the condition A and for the case the bias sputtering of the Ta film is conducted under the condition B. Here, it should be noted that the sputter-etching at the bottom part of the via-hole 13A and the sputter-etching at the bottom part of the interconnection trench 15A are conducted simultaneously by using the magnetron sputtering apparatus 100 of FIG. 3.

Referring to FIG. 6A, it can be seen that there is caused sputter-etching of the Ta film at the bottom part of the via-hole 13A with the depth of about 19 nm in the case the bias sputtering process is conducted under the condition A, while the sputter-etching with the generally same depth of about 20 nm is caused at the bottom part of the interconnection trench 15A when the sputter-etching process is conducted under the same condition A.

In the case of conducting the bias sputtering under the condition B, on the other hand, there is caused sputter-etching with the depth of about 19 nm in the Ta film at the bottom part of the via-hole 13A similarly to the case of FIG. 6A, while it should be noted that the amount of the sputter-etching at the bottom part of the interconnection trench 15A is only about 5 nm. This means that is possible to carry out the sputter-etching selectively at the bottom part of the via-hole 13A while leaving the bottom part of the interconnection trench 15A substantially unetched.

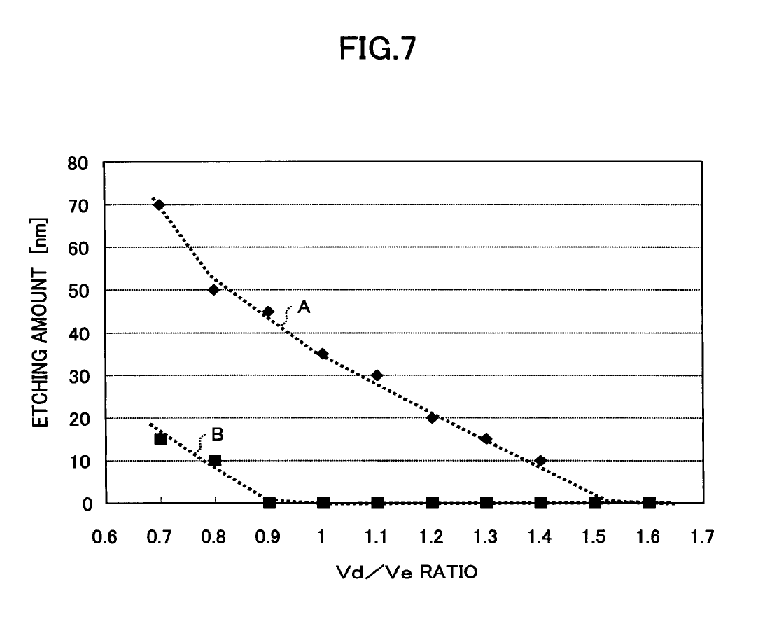

FIG. 7 is a diagram showing the relationship between the sputter-etching amount of the interconnection pattern 11A exposed at the bottom part of the via-hole 13A and the sputter-etching amount of the interconnection pattern 11A exposed at the bottom part of the interconnection trench 15A for the case the ratio Vd/Ve between the deposition rate Vd and the sputter-etching rate Ve is changed variously. In FIG. 7, it should be noted that the curve A represents the sputter-etching amount at the bottom part of the via-hole 13A while the curve B shows the sputter-etching amount at the bottom part of the interconnection trench 15A.

Referring to FIG. 7, it can be seen that, in the case the Vd/Ve ratio falls in the range of 0.9-1.5, it is possible to sputter-etch the bottom part of the via-hole 13A, without sputter-etching the bottom part of the interconnection trench 15A, and thus, it is possible to form the desired depression in the interconnection pattern 11A underneath selectively in correspondence to the via-hole 13A.

In the case the Vd/Ve ratio has missed the foregoing range and is reduced below 0.9, there starts sputter-etching also at the bottom part of the interconnection trench 15A, while this means that the structure explained previously with reference to FIG. 2B is formed. On the other hand, in the case the Vd/Ve ratio has missed the foregoing range and exceeded 1.5, the sputter-etching action is no longer effective even at the bottom part of the via-hole 13A, and it is not possible to form the desired depression in the interconnection pattern 11A.

From FIG. 7, it can be seen that it is preferable to carry out the deposition of the barrier metal film 16 under the condition in which the Vd/Ve ratio is equal to or larger than 0.9 but not exceeding 1.5.

### First Embodiment

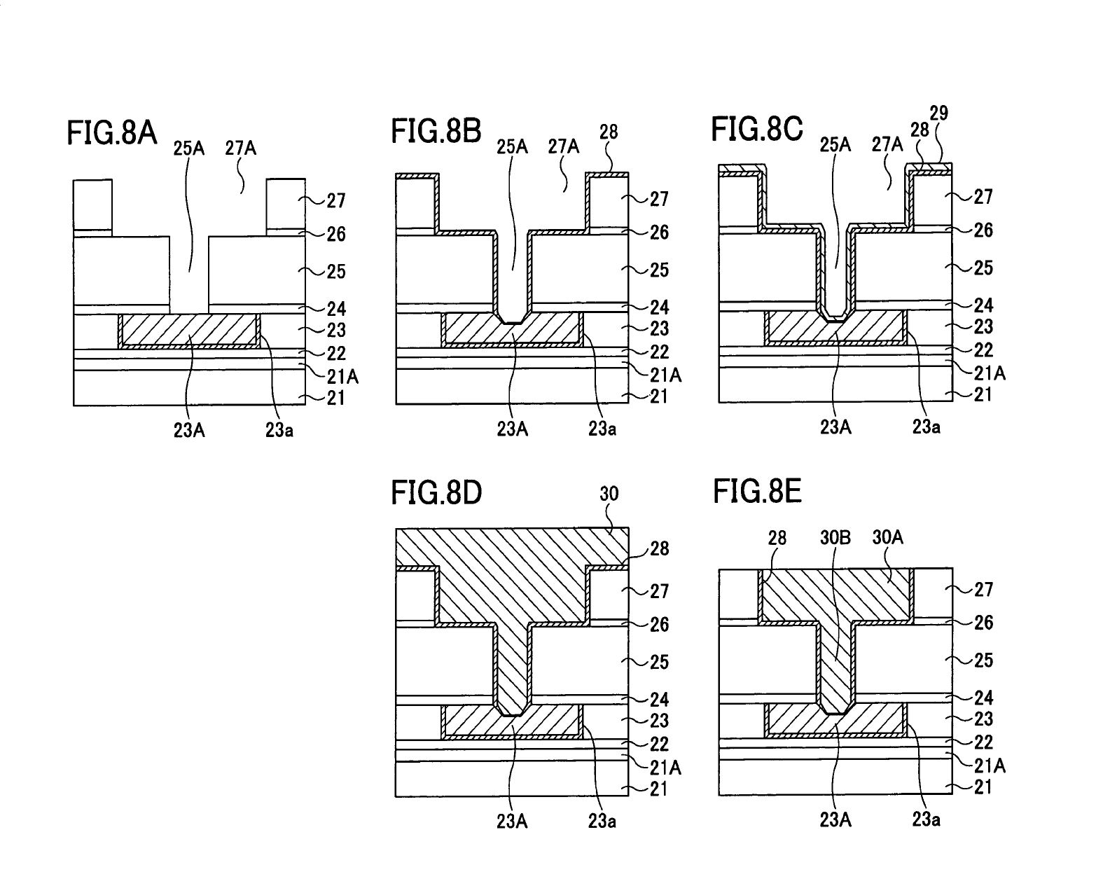

FIGS. 8A-8E are diagrams showing the fabrication process of a semiconductor device having a multilayer interconnection structure according to a first embodiment of the present invention.

Referring to FIG. 8A, there is formed an active device such as a transistor not illustrated on a silicon substrate 21 and the silicon substrate 21 is covered by an insulation film 21A.

On the insulation film 21A, there is formed an interlayer insulation film 23 via an etching stopper film 22 such as SiC or SiN, wherein an interconnection pattern 23A of Cu, or the like, is embedded in the interlayer insulation film 23 via a barrier metal film 23a such as Ta.

On the interlayer insulation film 23, there is formed a next interlayer insulation film 25 of the thickness of 200 nm, for example, via an etching stopper film 24 of SiC, SiN, or the like, formed with the thickness of 50 nm, for example.

For the interlayer insulation films 23, 25 and 27, it is possible to use low-K dielectric film of inorganic or organic material such as NCS (Nano-Clustering-Silica), LKD (Low-K Dielectrics), Porous-SiLK (Porous-Si-Low-K), or the like. Such interlayer insulation films can be formed by a coating process or CVD process. Further, the etching stopper films 22, 24 and 26 can be formed by a CVD process.

In the step of FIG. 8A, there is formed an interconnection trench 27A in the interlayer insulation film 27 so as to expose the surface of the interlayer insulation film 25 the a width of 200 nm, for example, and a via-hole 25A exposing the interconnection pattern 23A is formed in the interconnection trench 27A with a diameter of 70 nm, for example.

Next, in the step of FIG. 8B, the structure of the FIG. 8A is introduced into the magnetron sputtering apparatus 100 of the FIG. 3, and a barrier metal film 28 of refractory metal element such as Ta, Ti, W, Zr, or the like, or an alloy thereof is deposited so as to cover the sidewall surface and bottom surface of the interconnection trench 27A and further the sidewall surface and the bottom surface of the via-hole 25A. Further, it is possible to use a conductive nitride film of such refractory metal elements for the barrier metal film.

Thereby, it should be noted that the present embodiment carries out the deposition process of the barrier metal film 28 of the FIG. 8B in two steps, the first step being conducted under the condition in which the Vd/Ve ratio is set sufficiently larger than 1, and the second step being conducted by setting the Vd/Ve ratio to 0.9 or more but not exceeding 1.5.

In the case of forming the barrier metal film 28 by a Ta film, for example, the first step is conducted by setting the target electric power density applied to the target 104 to 320-640 mW/m², such as 640 mW/m², for example, and by setting the bias electric power density applied to the substrate W to be processed to 0-40 mW/m², such as 3 mW/m², in correspondence to the condition C of FIG. 5. Further, in the second step, the target electric power density applied to the target 104 is set up to 10-60 mW/m² and the bias electric power density applied to the substrate W is set up to 3-20 mW/m² such as 10 mW/m² in correspondence to the condition B of the FIG. 4. Further, it is possible to conduct the bias sputtering process in the process pressure range of 1×10⁻²˜1×10⁻¹ Pa throughout the first and second steps.

In the foregoing first step, the barrier metal film 18 is deposited with a film thickness of 16 nm, for example, while in the second step, there occurs little deposition in the barrier metal film 28. Conversely, there is caused sputter-etching in the Cu interconnection pattern 23A exposed at the bottom part of the via-hole 25A in the second step, and there is formed a depression at the bottom of the via-hole 25A with the depth of 10 nm or more. Thereby, the barrier metal film 18 deposited on the bottom part of the via-hole 25A causes re-deposition on the sidewall surface of the via-hole 25A after being sputter-etched, and it becomes possible to form the barrier metal film 28 on the sidewall surface of the via-hole 25A with sufficient thickness, even in the case the via-hole 25A has a large aspect ratio (depth/diameter ratio) and it is difficult to form a barrier metal film on the sidewall surface of the via-hole by way of a sputtering process.

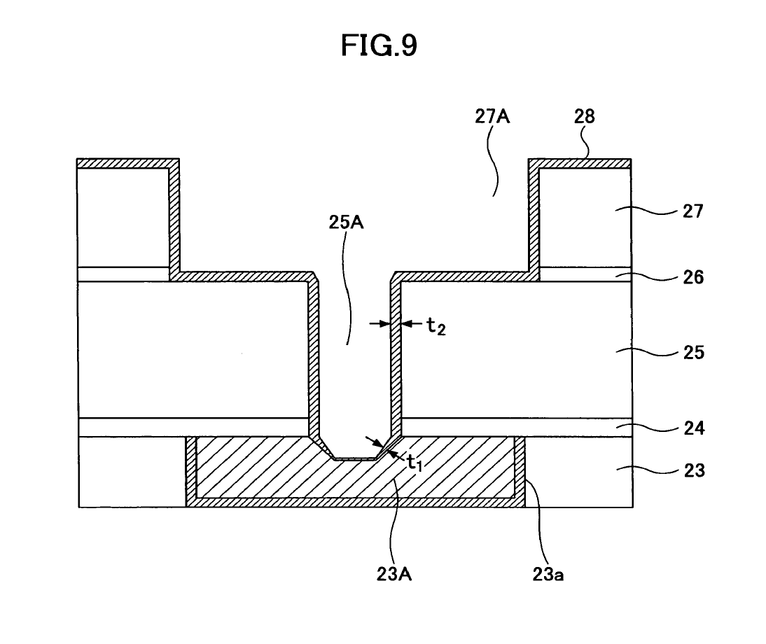

On the other hand, there occurs no sputter-etching at the bottom part of the interconnection trench 27A in any of the first and second steps, and as a result, there is obtained a structure shown schematically in FIG. 9, in which the thickness t₂ of the barrier metal film 28 at the sidewall surface of the via-hole 25A is larger than the thickness t₁ of the barrier metal film 28 at the bottom part of the via-hole 25A by 1.5 times or more (t₂>1.5t₁). Thereby, it should be noted that there occurs no sputter-etching at the bottom part of the interconnection trench 27A there is formed a flat surface corresponding to the top principal surface of the interlayer insulation film 25. In one example, the film thickness t2 has a value of 4-8 nm in the case the film thickness t1 has the value of 2-3 nm.

Next, in the step of FIG. 8C, a seed layer 29 of Cu or Cu alloy is formed on the structure of FIG. 8B by a sputtering process or CVD process with a film thickness of 40-150 nm, and a Cu layer 30 is formed on the interlayer insulation film 27 by conducting an electrolytic plating process in the step of FIG. 8B while using the Cu seed layer 29 as an electrode, such that the Cu layer 28 fills the interconnection trench 27A and the via-hole 25A via the barrier metal film 28.

In the case of forming the seed layer 29 by the sputtering of Cu in the step of FIG. 8C, the sputtering process may be conducted by setting the processing pressure to the range of 1×10⁻⁵-10 Pa, the target electric power density to 160-960 mW/m², and the bias electric power density to 6-16 mW/m². In the step of FIG. 8D, the electrolytic plating process may be conducted by supplying the electric current with a current density of 7-30 A/cm² in a copper sulfate bath, and the Cu layer 30 is formed with the film thickness of 500-2000 nm, for example.

Further, in the step of FIG. 8E, the Cu layer 30 on the interlayer insulation film 27 is polished out by a chemical mechanical polishing process that uses an organic acid slurry, for example, until the surface of the interlayer insulation film 27 is exposed. Thereby, a multilayer interconnection structure is obtained such that that the interconnection trench 27A and the via-hole 25A are filled respectively with a Cu interconnection pattern 30A and a Cu via-plug 30B.

With such a multilayer interconnection structure in which the Cu via-plug 30B invades beyond the surface of interconnection pattern 23A with a depth of 5 nm or more, a highly reliable contact is realized between the Cu via-plug 30B and the interconnection pattern 23A. Further, the thickness of the barrier metal film 28 is reduced at the tip end part of the Cu via-plug 30B as noted before, while this contributes to realize low resistance contact.

Further, the bias sputtering condition of the second step of FIG. 8B is set gentle in that the Vd/Ve ratio is close to 1, and because of this, there occurs no loss in the barrier metal film 28 at the bottom part of the interconnection pattern 27A. Thus, there occurs no such a situation in which the Cu interconnection pattern 30A makes a contact with the interlayer insulation film 25.

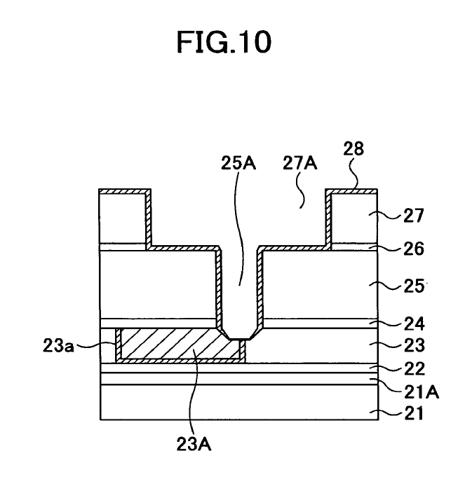

Further, there occurs no such a situation in which the barrier metal film 28 is lost at the tip end part of the Cu via-plug 30A, and thus, the tip end part of the Cu via-plug 30B is covered with the barrier metal film even in the case the via-hole 25A is offset from the interconnection pattern 23A as shown in FIG. 10. Thus, there occurs no diffusion of Cu from the Cu via-plug 30B into the interlayer insulation film 23.

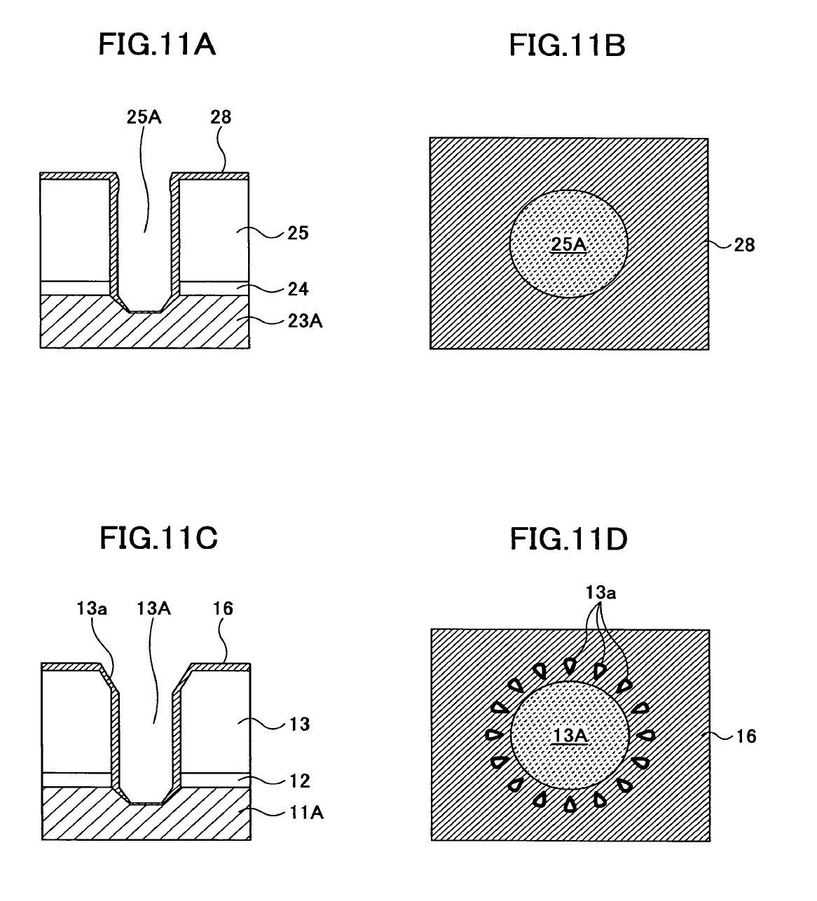

FIGS. 11A and 11B are respectively a cross-sectional view diagram and a plan view diagram showing the via-hole 25A in the state of the FIG. 8B, while FIGS. 11C and 11D are respectively a cross-sectional view diagram and a plan view diagram showing the via-hole 13A in the state of FIG. 2B explained previously.

Referring to FIGS. 11A and 11B, there occurs no substantial sputter-etching at the bottom surface of the interconnection trench 27A in the second step of the bias sputtering process with the present embodiment, and because of this, the shoulder part of the via-hole 25A undergoes no etching as can be seen in FIG. 11A. This means that there occurs no exposure of the interlayer insulation film 25 in the vicinity of the opening of the via-hole 25A in the plan view diagram of FIG. 11B.

With the example of FIGS. 11C and 11D according to the related art of the present invention, the shoulder part 13a of the via-hole 13A is subjected to the sputter-etching as shown in FIG. 11C, and as a result, there is a tendency that the barrier metal film 16 is lost partially in the vicinity of the via-hole 13A as shown in FIG. 10D. Thus, there is a tendency of the interlayer insulation film 13 being exposed. When the barrier metal film 16 is lost in the shoulder part 13a like this, the Cu plug 13B filling the via-hole 13A makes direct contact with the interlayer insulation film 13 and induces problem such as short circuit as the Cu atoms cause diffusion from the via-plug 13B into the interlayer insulation film 13.

FIGS. 11A-11D means that it is possible to judge whether or not there is caused anomaly such as partial loss of the barrier metal film by merely observing the opening region of the via-hole from the upper part.

Thus, by observing the state of the barrier metal film 28 in the vicinity of the opening region of the via-hole 25A from the upper part at the time of formation of the barrier metal film 28 in the step of the FIG. 8B, it becomes possible to conduct the process of checking the etching damages caused in the barrier metal film 28. Similarly, it becomes possible to check the etching damages caused in the barrier metal film 28 in the vicinity of the opening region of the interconnection trench 27A.

Further, in the present embodiment, it is possible to repeat the first step and the second step plural times alternately in the bias sputtering process of FIG. 8B.

### Second Embodiment

Meanwhile, the film thickness of the barrier metal film 28 necessary for protecting the bottom part of interconnection trench 27A at the time of the second step of the bias sputtering process of the FIG. 8B, and hence at the time of the sputter-etching process, changes depending on the Vd/Ve ratio at the time of the sputter-etching process. Thus, in the case the barrier metal film 28 is formed to have a large thickness at the bottom part of the interconnection trench 27A in the first step.

Further, it is also possible to use a value considerably smaller than 1.0 for the Vd/Ve ratio in the second step.

Thus, in this case, it becomes possible to increase the amount of etching quantity in the second step of FIG. 8B as compared with the embodiment explained previously.

On the other hand, in the case the barrier metal film 28 formed on the bottom part of the interconnection trench 27A has a small film thickness, there is a need of suppressing the amount of etching at the time of the sputter-etching process in accordance with the previous embodiment.

Thus, the present embodiment controls the ratio Td/Te of the cumulative deposition amount Td of the barrier metal film 28 deposited on the field part, in other words, on the flat part or principal surface of the insulation film 27, in the first and second steps, with regard to the cumulative etching amount Te indicative of the amount of the barrier metal film 28 removed from the foregoing field part in the first and second steps, to an appropriate value in order to protect the bottom part of the interconnection trench 27A by the barrier metal film 28 in the first and second steps of the bias sputtering process of FIG. 8B, noting the fact that there occurs deposition and sputter-etching simultaneously in the first step and that there occurs deposition and sputter-etching simultaneously also in the second step.

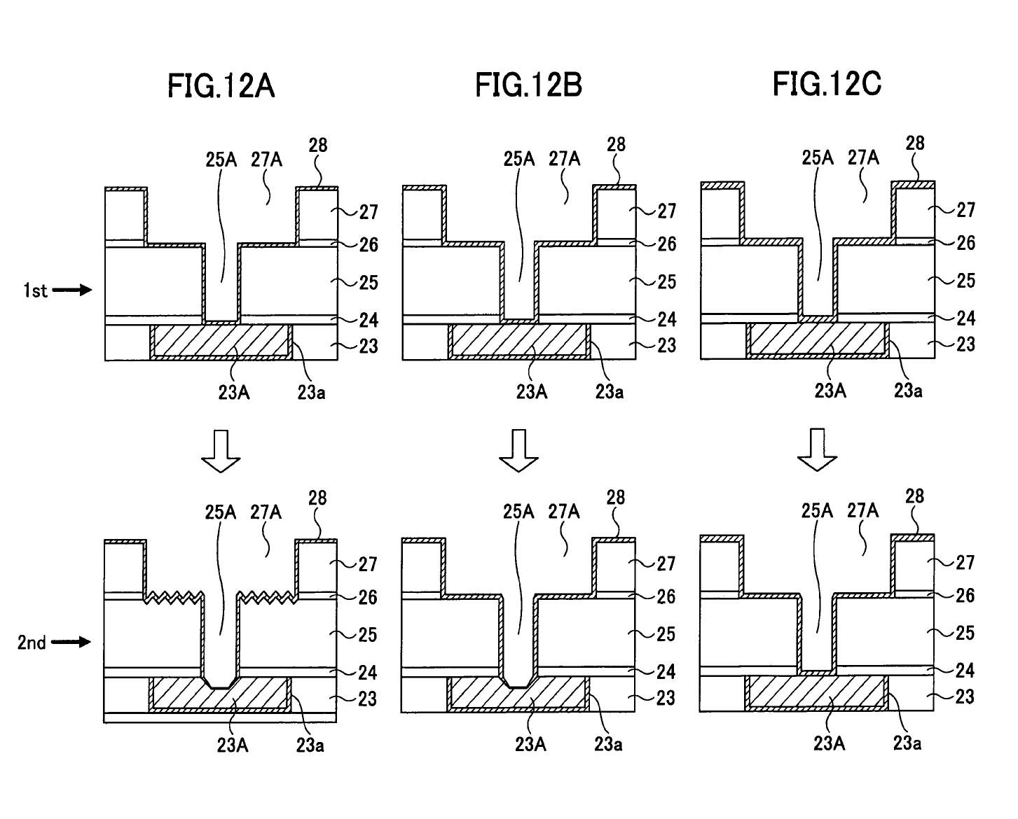

FIGS. 12A-12C are diagrams showing the shape of the interconnection trench 27A and the via-hole 25A for the case the deposition amount and the etching amount of the barrier metal film 28 on the flat surface corresponding to eth bottom part of the interconnection trench 27A is changed between the first step (1st) and the second step (2nd) of the bias sputtering process of FIG. 8B. In each of FIGS. 12A-12C, it should be noted that the first step and second step of the bias sputtering process are conducted under the condition shown in Table 2, wherein it should be noted that, in the first step of FIG. 12A, the deposition amount at the bottom surface of the interconnection trench 27A is 5 nm while the etching amount at the bottom surface is 1 nm. Further, it can be seen that, in the second step of FIG. 12A, the deposition amount at the bottom surface of the interconnection trench 27A is 15 nm while the etching amount at the bottom surface is 15 nm. Further, it can be seen that, in the first step of FIG. 12B, the deposition amount at the bottom surface of the interconnection trench 27A is 15 nm while the etching amount at the bottom surface is 2 nm. In the second step of FIG. 12B, it can be seen that the deposition amount at the bottom surface of the interconnection trench 27A is 15 nm while the etching amount at the bottom surface is 15 nm. Further, in the first step of FIG. 12C, it can be seen that the deposition amount at the bottom surface of the interconnection trench 27A is 40 nm while the etching amount at the bottom surface is 3 nm. In the second step of FIG. 12C, it can be seen that the deposition amount at the bottom surface of the interconnection trench 27A is 15 nm while the etching amount at the bottom surface is 15 nm.

TABLE 2

| | | (A) | (B) | (C) |
|---|---|---|---|---|
| First | Target Power | 640 | 640 | 640 |
| step | Density (mW/m²) | | | |
| | Bias Power | 3 | 3 | 3 |
| | Density (mW/m²) | | | |
| | Pressure (Pa) | 4E−2 | 4E−2 | 4E−2 |
| Second | Target Power | 100 | 100 | 100 |
| step | Density (mW/m²) | | | |
| | Bias Power | 10 | 10 | 10 |
| | Density (mW/m²) | | | |
| | Pressure (Pa) | 1E−2-1E−1 | 1E−2-1E−1 | 1E−2-1E−1 |

Thus, with the example of FIG. 12A, it can be seen that the cumulative deposition amount Td of the steps 1 and 2 is 20 nm while the cumulative etching amount Te of the steps 1 and 2 is 16 nm. In this case, therefore, there occurs partial loss of the barrier metal film 28 at the bottom part of the interconnection trench 27A, in correspondence to the Td/Te ratio between the cumulative deposition amount Td and the cumulative etching amount Te of 1.25.

In the example of FIG. 12B, on the other hand, it can be seen that the cumulative deposition amount Td of the steps 1 and 2 is 30 nm while the cumulative etching amount Te of the steps 1 and 2 is 17 nm. In this case, therefore, the loss of the barrier metal film 28 at the bottom part of the interconnection trench 27A is prevented, and there is formed a depression invading the interconnection pattern 23A at the bottom part of the via-hole 25A. In the case of FIG. 12B, it should be noted that the Td/Te ratio between the cumulative deposition amount Td and the cumulative etching amount Te is 1.76.

In the example of FIG. 12C, on the other hand, it can be seen that the cumulative deposition amount Td of the steps 1 and 2 is 55 nm while the cumulative etching amount Te of the steps 1 and 2 is 18 nm. In this case, therefore, the loss of the barrier metal film 28 at the bottom part of the interconnection trench 27A is prevented, while formation of depression invading the interconnection pattern 23A at the bottom part of the via-hole 25A is also suppressed.

While the range of the Td/Te ratio that causes formation of the sputter etching at the bottom part of the via-hole 25A while suppressing the loss of barrier metal 28 at the bottom of the interconnection trench 27A changes depending on the sputter-etching rate at the bottom of the via-hole 25A and the sputter-etching rate at the bottom of the interconnection trench 27A, it can be concluded that there occurs at least partial loss of the barrier metal film 28 at the bottom part of the interconnection trench 27A when the foregoing ratio Td/Te is less than 1.5 and the interlayer insulation film 25 underneath is exposed. Further, it is concluded that, in the case the Td/Te ratio exceeds 3.0, no sufficient sputter-etching is attained at the bottom part of the via-hole 25A.

From the foregoing, it is concluded that the Td/Te ratio is controlled preferably to be equal to or larger than 1.5 but not exceeding 3.0 (1.5≦Td/Te≦3.0) in the bias sputtering process of FIG. 8B throughout the first and second steps thereof.

While it is possible to control the ratio of the etching rate at the bottom of the via-hole 25A and the etching rate at the bottom of the interconnection trench 27A by controlling the Vd/Ve ratio as explained with reference to FIG. 7, there are cases in which it is physically difficult to suppress the loss of the barrier metal film 28 at the bottom surface of the interconnection trench 27A completely, and thus, it is preferable to use the control of the Td/Te ratio of the present embodiment, in addition to the control of the Vd/Ve ratio.

In the case the Td/The ratio is controlled to the foregoing range, the ratio Vb/Vt of the etching rate Vb at the bottom part of the via-hole 25A and the etching rate Vt at the bottom part of the interconnection trench 27A is maintained to be equal to or larger than 3 (Vb/Vt≧3), and thus, it becomes possible to carry out the etching process at the bottom part of the via-hole 25A while suppressing the etching at the bottom part of the interconnection trench 27A.

While the present invention has been explained with regard to preferred embodiments, it should be noted that the present invention is by no means limited to such particular embodiments and various variations and modifications may be made without departing from the scope of the present invention.

What is claimed is:

1. A method for fabricating a semiconductor device, comprising the steps of:
forming an opening in an insulation film covering a conductor pattern so as to expose said conductor pattern;
depositing a conductor film on said insulation film so as to cover continuously a principal surface of said insulation film and a sidewall surface and a bottom surface of said opening; and
depositing a conductor material on said insulation film via said conductor film such that said conductor material fills said opening via said conductor film,
wherein said step of depositing said conductor film comprises:
a first sputtering step that deposits said conductor film under a first condition in which a deposition rate on said principal surface of said insulation film that becomes larger than a sputter-etching rate on said principal surface; and
a second sputtering step that deposits said conductor film under a second condition in which a deposition rate on said principal surface of said insulation film that becomes generally equal to a sputter-etching rate on said principal surface.

2. The method as claimed in claim 1, wherein said first and second sputtering steps are repeated plural times in said step of depositing said conductor film.

3. The method as claimed in claim 1, wherein said first condition is set such that a surface of said conductor pattern is not removed at said opening in said first sputtering step and wherein said second condition is set such that a part of said surface of said conductor pattern is removed in said second sputtering step.

4. The method as claimed in claim 1, wherein said first and second conditions are determined in terms of a ratio Vd/Ve between a deposition rate Vd and a sputter-etching rate Ve on said principal surface of said insulation film, such that Vd/Ve>1 is met in said first condition and such that 0.9≦Vd/Ve≦1.4 is met in said second condition.

5. The method as claimed in claim 1, wherein said first and second conditions are determined in terms of a ratio Td/Te between a cumulative deposition amount Td and a cumulative etching amount Te of said conductor film on said principal surface of said insulation film in said first and second sputtering steps, such that 1.5≦Td/Te≦3.0 is met.

6. The method as claimed in claim 1, wherein said second sputtering step condition is determined in terms of ratio Vb/Vt between a sputter-etching rate V_{b} at a bottom part of a via-hole and a sputter-etching rate Vt at a bottom part of interconnection trench, such that Vb/Vt≧3 is met in said second condition.

7. The method as claimed in claim 1, wherein said second sputtering step is conducted by setting a target power density to 10 mW/m² or more but not exceeding 160 mW/m² and by setting a substrate bias power density to 3 mW/m² or more but not exceeding 20 mW/m².

8. The method as claimed in claim 1, wherein said step of depositing said conductor film is conducted by setting a pressure of sputtering ion species to 1×10⁻² Pa or more but not exceeding 1×10⁻¹ Pa.

9. The method as claimed in claim 1, wherein said conductor film contains one or more refractory metal element selected from the group consisting of Ta, Ti, W and Zr.

10. The method as claimed in claim 1, wherein said step of filing said opening with said conductor material comprises the step of forming a seed layer of Cu or of a compound containing Cu on said conductor film; and filing Cu on said seed layer as said conductor material.

11. The method as claimed in claim 10, wherein said compound containing Cu contains one or more elements selected from the group consisting of Al, Ti, Zr, Ni, Ag and Pd.

12. The method as claimed in claim 1, further comprising the step of checking existence of an etching damage in said conductor film in the vicinity of said opening by observing a state of said conductor film from an upward direction of said insulation film.

13. The method as claimed in claim 2, wherein said first condition is set such that a surface of said conductor pattern is not removed at said opening in said first sputtering step and wherein said second condition is set such that a part of said surface of said conductor pattern is removed in said second sputtering step.

14. The method as claimed in claim 2, wherein said first and second conditions are determined in terms of a ratio Vd/Ve between a deposition rate Vd and a sputter-etching rate Ve on said principal surface of said insulation film, such that Vd/Ve>1 is met in said first condition and such that 0.9≦Vd/Ve≦1.4 is met in said second condition.

15. The method as claimed in claim 2, wherein said first and second conditions are determined in terms of a ratio Td/Te between a cumulative deposition amount Td and a cumulative etching amount Te of said conductor film on said principal surface of said insulation film in said first and second sputtering steps, such that 1.5≦Td/Te≦3.0 is met.

16. The method as claimed in claim 2, wherein said second sputtering step condition is determined in terms of ratio Vb/Vt between a sputter-etching rate Vb at a bottom part of a via-hole and a sputter-etching rate Vt at a bottom part of interconnection trench, such that Vb/Vt≧3 is met in said second condition.
